(19) United States
(12) Patent Application Publication
(10) Pub. No.: US 2025/0228093 A1
(43) Pub. Date: Jul. 10, 2025

(54) DISPLAY PANEL AND DISPLAY DEVICE

(71) Applicant: Hefei Visionox Technology Co., Ltd., Hefei (CN)

(72) Inventors: Jianjun LU, Hefei (CN); Cuili GAI, Hefei (CN); Enqing GUO, Hefei (CN); Long CHEN, Hefei (CN); Kangguan PAN, Hefei (CN); Shuang GUO, Hefei (CN); Yun CHENG, Hefei (CN); Xiaoyang JIN, Hefei (CN)

(73) Assignee: Hefei Visionox Technology Co., Ltd., Hefei (CN)

(21) Appl. No.: 19/088,999

(22) Filed: Mar. 25, 2025

Related U.S. Application Data
(63) Continuation of application No. PCT/CN2024/071757, filed on Jan. 11, 2024.

(30) Foreign Application Priority Data
Jul. 14, 2023 (CN) 202310871319.0

(51) Int. Cl. H10K 59/131; H10K 59/80

(52) U.S. Cl. CPC H10K 59/1315; H10K 59/8792

(57) ABSTRACT

Provided are a display panel. A non-display region of the display panel includes at least one arc angle region and a first power bus passing through the at least one arc angle region. The first power bus includes a first bus portion and a second bus portion. The first bus portion is disposed on a side of a display region and is electrically connected to the second bus portion. The first bus portion is configured to be connected to a power supply. Multiple power signal lines are also disposed in the display region. The power signal lines are electrically connected between the second bus portion in at least one arc angle region and the first bus portion. The current in the second bus portion in the arc angle region is shunted to the display region through the power signal lines disposed in the display region.

### CROSS-REFERENCE TO RELATED APPLICATIONS

This application is a continuation of International Patent Application No. PCT/CN2024/071757, filed on Jan. 11, 2024, which claims priority to Chinese Patent Application No. 202310871319.0, filed on Jul. 14, 2023, disclosures of both of which are incorporated herein by reference in their entireties.

### FIELD

The present application relates to the field of display technology, for example, a display panel and a display device.

### BACKGROUND

With the rapid development of organic light-emitting diode display panels, consumers have increasingly higher requirements on the appearance of a display device. Many display panels have evolved from traditional square structures to popular irregular structures. As a result, the display panels are prone to generating heat.

### SUMMARY

The present application provides a display panel and a display device.

According to one embodiment of the present application, a display panel is provided. The display panel includes a display region and a non-display region surrounding the display region. The non-display region includes at least one arc angle region.

The display panel also comprises a first power bus disposed in the non-display region, surrounding at least part of the display region, and passing through at least one arc angle region. The first power bus includes a first bus portion and a second bus portion. The first bus portion is disposed on a side of a display region and is electrically connected to the second bus portion. The first bus portion is configured to be connected to a power supply.

The display panel also comprises multiple power signal lines disposed in the display region. One or more power signal lines are electrically connected between the second bus portion in the least one arc angle region and the first bus portion.

According to another embodiment of the present application, a display device is provided. The display device includes the preceding display panel.

### BRIEF DESCRIPTION OF DRAWINGS

FIG. 1 is a diagram illustrating the structure of a display panel according to one or more embodiments of the present application.

FIG. 2 is a diagram illustrating the structure of another display panel according to one or more embodiments of the present application.

FIG. 3 is a diagram illustrating the structure of another display panel according to one or more embodiments of the present application.

FIG. 4 is a layout diagram of the display region of a display panel according to one or more embodiments of the present application.

FIG. 5 is a current emulation diagram of the display region of a display panel according to one or more embodiments of the present application.

FIG. 6 is a section view of a display panel according to one or more embodiments of the present application.

FIG. 7 is another section view of a display panel according to one or more embodiments of the present application.

FIG. 8 is a layout diagram of an arc angle region in the non-display region of a display panel according to one or more embodiments of the present application.

FIG. 9 is a current simulation diagram of an arc angle region in the non-display region of a display panel according to one or more embodiments of the present application.

FIG. 10 is a layout diagram of a side region in the non-display region of a display panel according to one or more embodiments of the present application.

FIG. 11 is a current simulation diagram of a side region in the non-display region of a display panel according to one or more embodiments of the present application.

FIG. 12 is a layout diagram of a lower bezel region in the non-display region of a display panel according to one or more embodiments of the present application.

FIG. 13 is a current simulation diagram of a lower bezel region in the non-display region of a display panel according to one or more embodiments of the present application.

FIG. 14 is a diagram illustrating the structure of a pixel circuit in a display panel according to one or more embodiments of the present application.

FIG. 15 is a diagram illustrating the structure of another display panel according to one or more embodiments of the present application.

FIG. 16 is a diagram illustrating the structure of a display device according to one or more embodiments of the present application.

### DETAILED DESCRIPTION

As described in the BACKGROUND, in the highlight mode of a display panel, the current in the display panel is relatively large. As a result, heat is generated easily in the display panel. Through research, the applicant finds that the reason is that the arc angle region of the display panel has a high degree of current aggregation and a large current density, resulting in the generation of a large amount of heat. For example, the display panel includes a display region and a non-display region surrounding the display region. The display region is provided with a light-emitting device. The display region is provided with a cathode wire. The current flowing through all the light-emitting devices in the display region is converged from a cathode to the cathode wire in the non-display region and finally flows back to a power chip. The current density in an arc angle region in the non-display region, especially the arc angle region more adjacent to the side of the power chip, is the largest, resulting in the generation of a large amount of heat. Thus, the temperature of the display panel is relatively high.

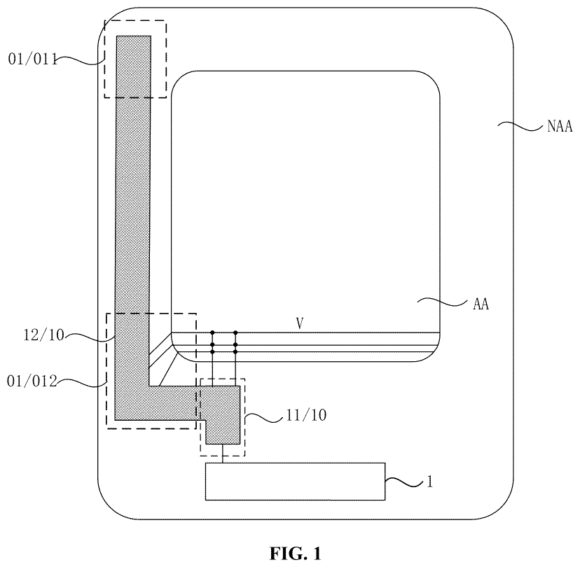

One or more embodiments of the present application provide a display panel. FIG. 1 is a diagram illustrating the structure of a display panel according to one or more embodiments of the present application. Referring to FIG. 1, the display panel includes a display region AA and a non-display region NAA surrounding the display region AA. The non-display region NAA includes at least one arc angle region 01.

The display panel also includes a first power bus 10 disposed in the non-display region NAA, surrounding at least part of the display region AA, passing through at least one arc angle region 01. The first power bus 10 includes a first bus portion 11 and a second bus portion 12. The first bus portion 11 is disposed on a side of the display region AA and is electrically connected to the second bus portion 12. The first bus portion 11 is configured to be connected to a power supply 1.

The display panel also includes multiple power signal lines V disposed in the display region AA. One or more power signal lines V are electrically connected between the second bus portion 12 in at least one arc angle region 01 and the first bus portion 11.

For example, the display panel also includes light-emitting devices disposed in the display region AA to implement display of the display panel. The non-display region NAA may be disposed around the display region AA. In one or more embodiments, the display region AA and non-display region NAA are all rounded rectangles, the non-display region NAA includes four arc angle regions 01. Two arc angle regions 01 are adjacent to the upper bezel region of the non-display region NAA, and the other two arc angle regions 01 are adjacent to the lower bezel region of the non-display region NAA. In other embodiments, the display panel may be another irregular display panel and may include only one, two, or more arc angle regions 01. This is not limited in the embodiments. In one or more embodiments, an example shows the case where the first power bus 10 is disposed around only part of the display region AA. In other embodiments of the present application, the first power bus 10 may surround the entire display region AA.

The first bus portion 11 is disposed in the non-display region NAA and is disposed adjacent to the power supply 1. For example, the power supply 1 is disposed in the lower bezel region of the non-display region NAA, and the first bus portion 11 is disposed in the lower bezel region. The power supply 1 may be configured to provide a power signal required by the cathode of the light-emitting device. The first power bus 10 may be a cathode wire configured to transmit the cathode signal of the light-emitting devices. The cathodes of at least part of the light-emitting devices are connected to the second bus portion 12 in the first power bus 10. The second bus portion 12 is connected to the first bus portion 11 through the power signal lines V in the display region AA. The current of the light-emitting devices flows through the second bus portion 12 connected to the light-emitting devices and the power signal lines V in the display region AA, then is converged to the first bus section 11, and finally is transmitted to the power supply 1. Thus, the current on the second bus portion 12 is shunted to the display region AA. It is to be noted that the power signal lines V may be disposed on the entire screen or may be disposed only in the display region AA corresponding to the arc angle region 01, which is not limited herein.

According to the display panel in one or more embodiments, the current in the second bus portion is shunted to the display region through the power signal lines disposed in the display region, the shunted current is then converged to the first bus portion through the power signal lines. In this manner, the current density on the second bus portion in the arc angle region is effectively reduced, and the heating of the screen caused by the excessive current in the arc angle region is reduced. Thus, the temperature of the display panel is reduced. In one embodiment, the first power bus is connected to the power signal lines, the resistance of the overall structure of the first power bus and the power signal lines is reduced compared with the resistance of the first power bus, and the voltage loss in the transmission process of a power signal may be reduced. Thus, the power consumption of the display panel is reduced. Further, the temperature of the display panel is reduced.

Further referring to FIG. 1, for example, the at least one arc angle region of the non-display region NAA includes a first arc angle region 011 and a second arc angle region 012. The distance between the first arc angle 011 region and the first bus portion 11 is greater than the distance between the second arc angle region 012 and the first bus portion 11.

At least the second bus portion 12 in the second arc angle region 012 is electrically connected to the first bus portion 11 through the power signal lines.

In one or more embodiments, the distance between the first arc angle region 011 and the first bus portion 11 may refer to the distance between the first bus portion 11 and the edge of the first arc angle region 011 most adjacent to the first bus portion 11. The distance between the second arc angle region 012 and the first bus portion 11 may refer to the distance between the first bus portion 11 and the edge of the second arc angle region 012 most adjacent to the first bus portion 11.

As described above, the current in the display region AA is finally converged to the power supply 1 through the first bus portion 11. Thus, the more adjacent to the arc angle region 01 of the first bus portion 11 is, the greater the current density is, and the easier it is to cause the temperature of the display panel to be too high. Thus, the second arc angle region 012 having a relatively large current density is configured to be electrically connected to the first bus portion 11 through the power signal lines V to shunt the current in the second arc angle region 012 through multiple power signal lines V, to reduce the current density at the second arc angle region 012. To further reduce the current density in the second arc angle region 012, shunting may also be performed on the first arc angle region 011 through multiple power signal lines V to avoid the excessive current density in the first arc angle region 011. In one embodiment, the magnitude of the current flowing into the second arc angle region 012 through the first arc angle region 011 is reduced, and the current density in the arc angle region 012 is reduced.

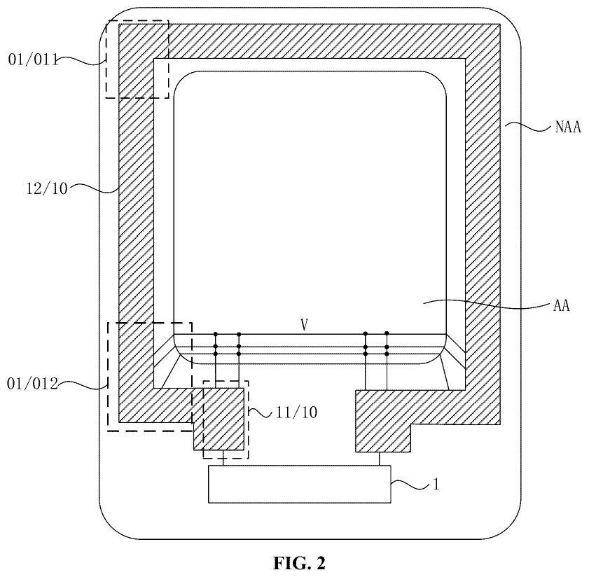

FIG. 2 is a diagram illustrating the structure of another display panel according to one or more embodiments of the present application. Compared with the display panel shown in FIG. 1, the display panel shown in FIG. 2 has a larger area surrounding the display region AA. Referring to FIGS. 1 and 2, for example, the first bus portion 11 and the second bus portion 12 are an integrated structure.

The first bus portion 11 and the second bus portion 12 are an integrated structure, and the preparation process may be simplified. No additional conductive structure needs to be disposed to connect the first bus portion 11 and the second bus portion 12.

In other embodiments of the present application, the first bus portion 11 and the second bus portion 12 may not be an integrated structure. The two may be electrically connected in the non-display region NAA in a manner of directly electrical connection or lapping.

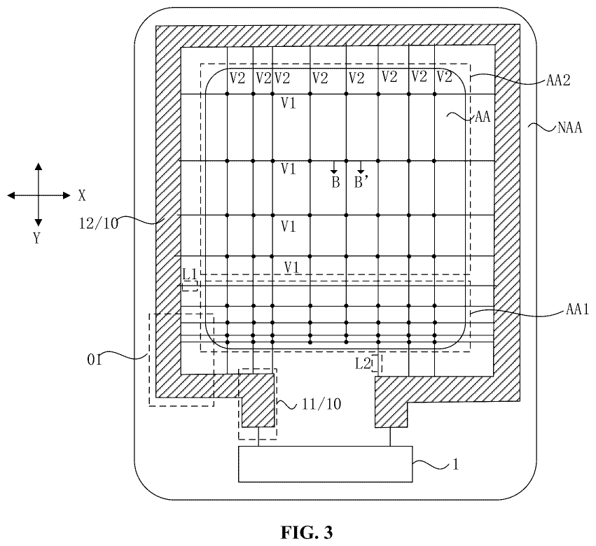

FIG. 3 is a diagram illustrating the structure of another display panel according to one or more embodiments of the present application. Referring to FIG. 3, for example, the non-display region NAA also includes one or more side regions adjacent to the arc angle region 01. The second bus portion 12 in at least one side region of the one or more side regions is electrically connected to the first bus portion 11 through one or more power signal lines.

For example, the non-display region NAA may include four side regions, namely a left bezel region, a right bezel region, an upper bezel region, and a lower bezel region. The second bus portion in at least one of the left bezel region, the right bezel region, the upper bezel region, or the lower bezel region may be electrically connected to the first bus portion 11 through multiple power signal lines. The second bus portion 12 in multiple side regions also has a certain degree of current aggregation. The current on the second bus portion 12 in the side region is shunted through multiple power signal lines to reduce the current density of the second bus portion 12 in the side region and reduce the overall temperature of the display panel. In one embodiment, after the current in the side region is shunted, the density of the current flowing into the second bus portion 12 in the arc angle region 01 through the side region is reduced. Thus, it is beneficial to reducing the temperature in the arc angle region. The second bus portion 12 in the side region is electrically connected to the first bus portion 11 through multiple power signal lines, and the voltage drop generated on a transmission path for transmitting the power signal by the second bus portion 12 may be reduced, to reduce the power consumption and improving the display uniformity.

Further referring to FIG. 3, for example, multiple power signal lines include one or more first power signal lines V1 and one or more second power signal lines V2. The first power signal lines V1 extend in a first direction X. The second power signal lines V2 extend in a second direction Y. The first direction X and the second direction Y intersect. The first power signal lines V1 are electrically connected to the second power signal lines V2. In the second direction Y, the first bus portion 11 is located on the side of the display region AA. The first bus portion 11 is electrically connected to the second power signal lines V2. The second bus portion 12 in the arc angle region 01 is electrically connected to one or more first power signal lines V1.

For example, the first direction X is the row direction in which light-emitting devices are arranged in the display panel. The second direction Y is the column direction in which the light-emitting devices are arranged. The multiple power signal lines include multiple first power signal lines V1 arranged in the second direction Y, and multiple second power signal lines V2 arranged in the first direction X. Any first power signal line V1 and any second power signal line V2 are electrically connected. Since the second power signal lines V2 extend in the second direction Y, and in the second direction Y, the first bus portion 11 is located on the side of the display region AA, that is, the first bus portion 11 is located on a side of the second power signal lines V2, the second bus portion 12 in the arc angle region 01 is electrically connected to the first power signal lines V1, the first power signal lines V1 are connected to the second power signal lines V2, and the second power signal lines V2 are connected to the first bus portion 11, and the current in the arc angle region 01 may be shunted into multiple second power signal lines V2 through multiple first power signal lines V1, and the multiple second power signal lines V2 then converge the current to the first bus portion 11.

The multiple first power signal lines V1 and the multiple second power signal lines V2 shunt the current in the arc angle region 01. Thus, the current density in the arc angle region 01 is reduced, and the heating of the screen caused by the excessive current in the arc angle region 01 is reduced. In one embodiment, the multiple first power signal lines V1 and the multiple second power signal lines V2 form a mesh structure. The resistance of the mesh structure is reduced compared with the resistance of only the power signal lines in the first direction X or the second direction Y, and the voltage loss in the transmission process of a power signal may be effectively reduced, and the power consumption of the display panel is reduced.

Further referring to FIG. 3, for example, the second bus portion 12 in at least one side region is electrically connected to one or more first power signal lines V1.

The current on the second bus portion 12 in the side region is shunted into the display region AA through multiple first power signal lines V1 and then the current is converged to the first bus portion 11 through the multiple second power signal lines V2. Compared with the case where the current only on the second bus portion 12 in the arc angle region 01 is shunted through the first power signal lines V1 and the second power signal lines V2, the current on the second bus portion 12 in the side region is also shunted through the first power signal lines V1 and the second power signal lines V2, and the current density in the arc angle region 01 may be further reduced, and the heating of the screen caused by the excessive current in the arc angle region 01 is alleviated. In one embodiment, after the current in the side region is shunted, the current density of the side region is effectively reduced, and the heating of the side region is alleviated, and the service life of the display panel is prolonged.

Further referring to FIG. 3, for example, the display region AA includes a first display sub-region AA1 and a second display sub-region AA2. The second display sub-region AA2 is located on the side of the first display sub-region AA1 facing away from the first bus portion 11. The density of first power signal lines V1 in the second display sub-region AA2 is less than the density of first power signal lines V1 in the first display sub-region AA1.

For the non-display region NAA, in the second direction Y, the more adjacent to the first bus portion 11 is, the greater the current density on the second bus portion 12 is. Thus, it is necessary to set the density of first power signal lines V1 in a display region corresponding to the second bus portion 12 having a relatively large current density to be relatively large. Thus, it is ensured that the current on the second bus portion 12 having a relatively large current density is shunted through a larger number of first power signal lines V1 to improve the shunting effect. In one embodiment, it is necessary to set the density of first power signal lines V1 in a display region corresponding to the second bus portion 12 having a relatively small current density to be relatively small. In addition to the shunting effect, the number of first power signal lines V1 in the display panel may be reduced, and the wiring difficulty may be reduced.

Further referring to FIG. 3, for example, in a direction from the second display sub-region AA2 to the first display sub-region AA1, the density of first power signal lines V1 gradually increases.

In the direction from the second display sub-region AA2 to the first display sub-region AA1, the current density of the second bus portion 12 in the non-display region NAA gradually increases. Thus, in the region of the second display sub-region AA2 further away from the first display sub-region AA1, the density of first power signal lines V1 is smaller, the first power signal lines V1 having a relatively small density may satisfy the shunting effect, and there is no need to dispose too many first power signal lines V1. In the direction from the second display sub-region AA2 to the first display sub-region AA1, the density of first power signal lines V1 gradually increases. The shunting effect for the second bus portion 12 at multiple positions in the non-display region NAA is ensured, and moreover, the number of first power signal lines V1 in the display panel may be reduced, and the wiring difficulty may be reduced.

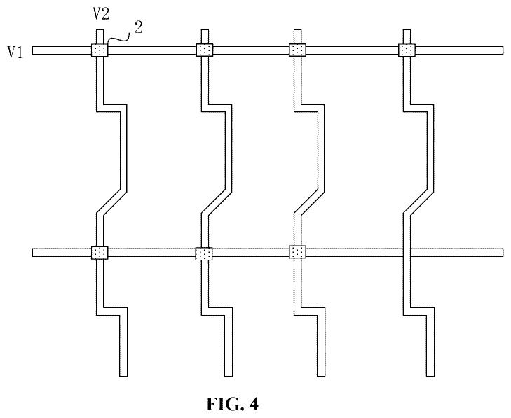

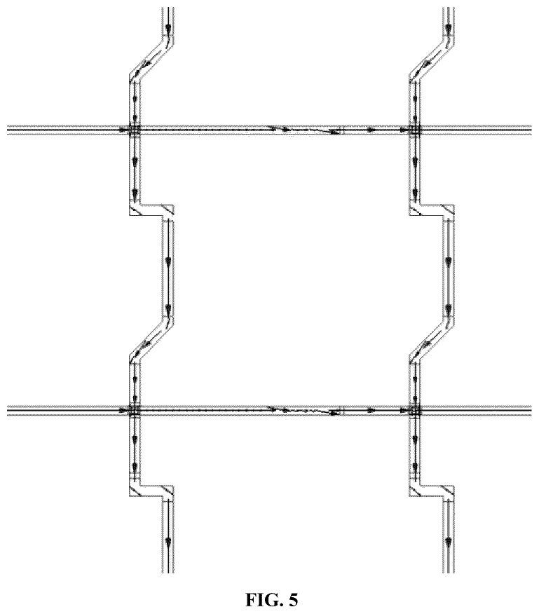

FIG. 4 is a layout diagram of the display region of the display panel shown in FIG. 3. FIG. 5 is a current simulation diagram of the display region of the display panel shown in FIG. 3. Referring to FIGS. 3, 4, and 5, for example, the display panel includes a substrate and an array film on the substrate. The array film includes multiple stacked metal layers. The first power signal lines V1 and the second power signal lines V2 are disposed in at least one metal layer of the multiple stacked metal layers.

The substrate may be a flexible substrate, such as a plastic substrate made of polyethylene ether phthalate, polyarylate, polyimide (PI), polyester polyethylene terephthalate (PET), polycarbonate (PC), cycloolefin polymer (COP), cellulose acetate propionate (CAP), polyethersulfone (PES), polyacrylate (PAR), polyetherimide (PEI), polyethylene naphthalate (PEN), polyphenylene sulfide (PPS), polyallyl ester, and cellulose triacetate (TAC), which has excellent heat resistance and durability. The substrate may be a rigid substrate, for example, a glass substrate. The display panel includes a light-emitting device. The array film may include a driver circuit layer disposed between the substrate and the light-emitting device. A pixel circuit is disposed in the driver circuit layer to drive the light-emitting device to emit light. The array film includes multiple stacked metal layers to form the source electrode and the drain electrode of a transistor included in the pixel circuit. The first power signal lines V1 and the second power signal lines V2 may be located in the same metal layer of the array film or may be located in two metal layers, respectively. The first power signal lines V1 and the second power signal lines V2 are disposed in at least one metal layer of the array film. The existing metal layer in the display panel may be used to prepare first power signal lines V1 and the second power signal lines V2. There is no need to dispose additional metal layers for preparing the first power signal lines and the second power signal lines. Thus, the thickness of the display panel is reduced, and the structure of the display panel is simplified. In other embodiments, at least one additional metal layer may also be added to the existing array film, and the first power signal lines V1 and the second power signal lines V2 may be disposed in the at least one additional metal layer.

One or more embodiments exemplarily show that the first power signal lines V1 and the second power signal lines V2 are located at different layers, and the two are connected through vias 2.

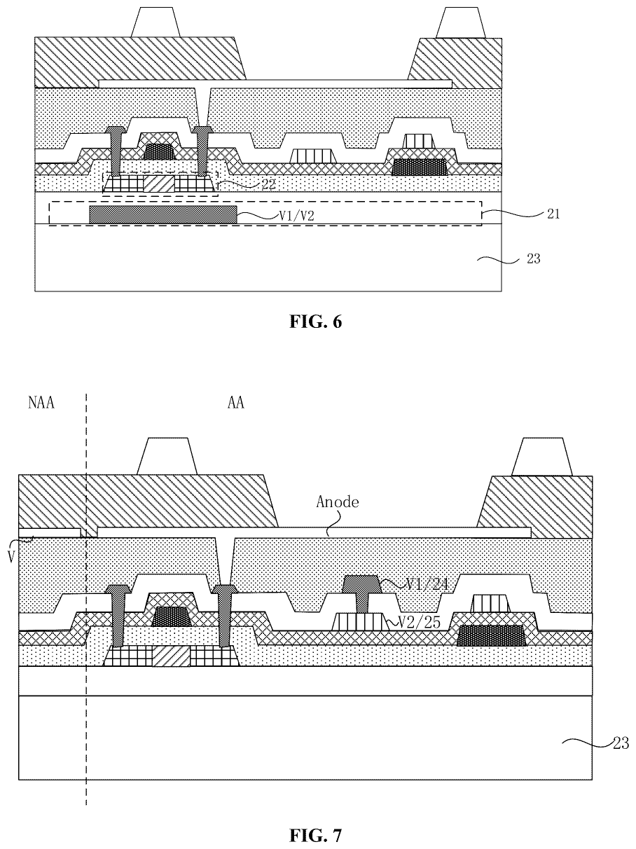

FIG. 6 is a section view of a display panel according to one or more embodiments of the present application. FIG. 6 is a section view taken along BB′ of FIG. 3. Referring to FIGS. 3 and 6, for example, the multiple stacked metal layers include a light-shielding layer 21. The light-shielding layer 21 is located between an active layer 22 in the array film and the substrate 23. The first power signal lines V1 and the second power signal lines V2 are located in the light-shielding layer 21.

The array film also includes the active layer 22. The active layer may be an amorphous silicon layer, a polysilicon layer, or a metal oxide layer. For example, the orthographic projection of the light-shielding layer 21 on the substrate covers at least part of the orthographic projection of the active layer 22 on the substrate. The active layer 22 includes the channel of the transistor in the display panel. The channel of the transistor is irradiated by light, thus the leakage current of the transistor is increased, and the electrical property of the transistor is affected. The light-shielding layer 21 is disposed, and the leakage current of the transistor in the display panel may be small, and the good electrical property of the transistor is ensured.

The first power signal lines V1 and the second power signal lines V2 disposed in the light-shielding layer 21 may be used as a light-shielding structure. In one embodiment, the first power signal lines V1, the second power signal lines V2, and the light-shielding structure are disposed in the light-shielding layer 21. The first power signal lines V1 and the second power signal lines V2 may be disposed in one light-shielding layer 21. Thus, it is beneficial to reducing the thickness of the display panel, and it is ensured that the display panel is relatively light and thin. In one or more embodiments exemplarily show that the first power signal lines V1 and the second power signal lines V2 disposed in the light-shielding layer 21 are used as a light-shielding structure. The two are disposed in one light-shielding layer 21.

FIG. 7 is another section view of a display panel according to one or more embodiments of the present application. FIG. 7 is a section view taken along BB′ of FIG. 3. Referring to FIGS. 3 and 7, for example, the first power signal lines V1 are located in a first metal layer 24. The second power signal lines V2 are located in a second metal layer 25. The second metal layer 25 is located on a side of the first metal layer 24 adjacent to the substrate 23.

The multiple stacked metal layers include the first metal layer 24 and the second metal layer 25 that are stacked. The first metal layer 24 and the second metal layer 25 are insulated from each other. The materials of the first metal layer and the second metal layer may be Mo. The display panel includes a pixel circuit. The pixel circuit includes a storage capacitor and at least two transistors. The second metal layer 25 may include a pole plate of the storage capacitor. The first metal layer 24 may include a source electrode and drain electrode of the transistor. To simplify the wiring design of a single metal layer, the first power signal lines V1 and the second power signal lines V2 may be disposed in different films. For example, the first power signal lines V1 are located in the first metal layer 24, and the second power signal lines V2 are located in the second metal layer 25. In other embodiments, in an arrangement where the first power signal lines V1 and the second power signal lines V2 are located at different layers, the first power signal lines V1 and the second power signal lines V2 are electrically connected in a punching manner or are switched through other conductive structures, which is not limited herein.

Further referring to FIG. 7, for example, the display panel also includes a first electrode (Anode) and a second electrode. The second electrode is disposed on the side of the first electrode facing away from the array film. The second bus portion is electrically connected to the second electrode.

The first electrode is an anode of the light-emitting device. The second electrode is a cathode of the light-emitting device. The anode and the cathode may include multi-layer structures of ITO, Ag, and ITO. The first electrode (Anode) may be an independent structure. Multiple first electrodes are insulated from each other. One first electrode (Anode) corresponds to one light-emitting device. The second electrode may be a whole surface structure, connected to the second bus portion, and configured to receive the cathode signal transmitted on the second bus portion.

For example, the first power bus V and the first electrode (Anode) are disposed in the same layer. The first power bus Vis insulated from the first electrode Anode. Further, the first power bus V may be prepared in the same preparation process as the first electrode (Anode), and the process step of the preparation of the display panel is saved, and the preparation process of the display panel is simplified.

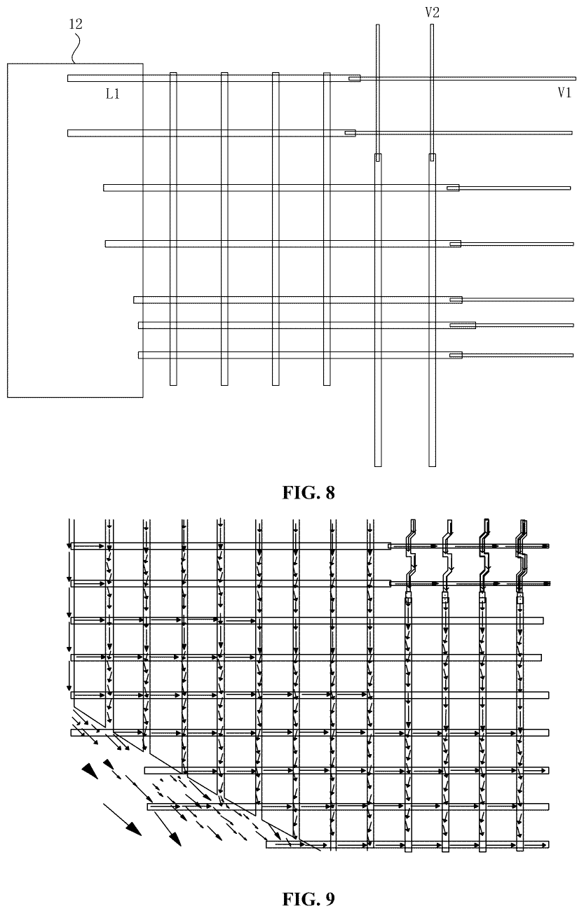

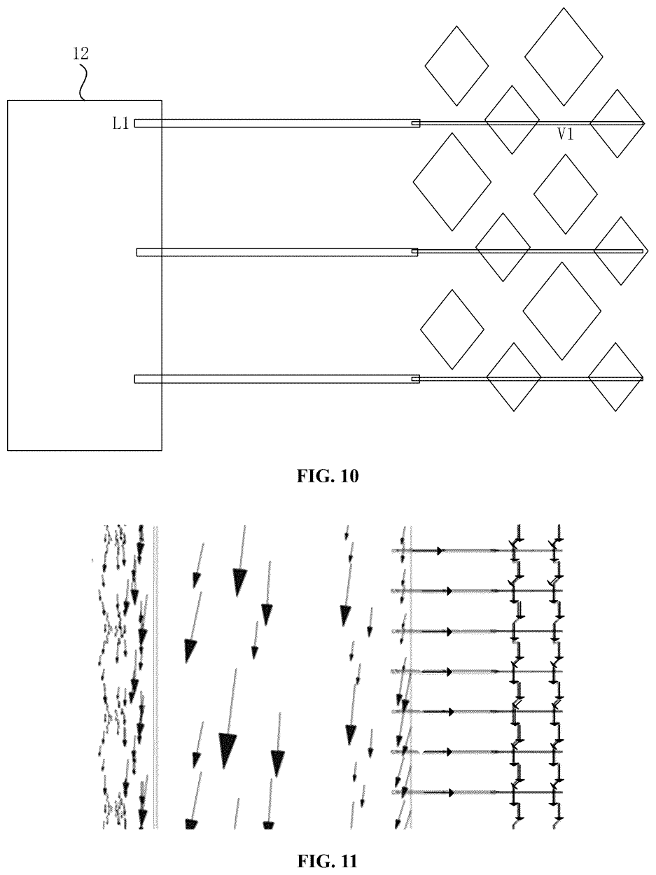

FIG. 8 is a layout diagram of an arc angle region in the non-display region of a display panel shown in FIG. 3. FIG. 9 is a current simulation diagram of an arc angle region in the non-display region of a display panel shown in FIG. 3. FIG. 10 is a layout diagram of a side region in the non-display region of a display panel shown in FIG. 3. FIG. 11 is a current simulation diagram of a side region in the non-display region of a display panel shown in FIG. 3. The arrows in FIG. 9 and FIG. 11 indicate the direction of current. Referring to FIG. 3, FIG. 8, FIG. 9, FIG. 10, and FIG. 11, the display panel also includes a first adapter line L1. The first adapter line L1 is located on a third metal layer. The third metal layer is located on the side of the first metal layer facing away from the substrate (for example, for the section view of the display panel shown in FIG. 7, the third metal layer is located between the layer where the first electrode is located and the first metal layer, and the third metal layer is not shown in FIG. 7).

A first end of the first adapter wire L1 is electrically connected to the second bus portion 12. A second end of the first adapter line L1 is electrically connected to the first power signal lines V1.

The materials of the third metal layer and the first adapter line L1 may be Ti/Al/Ti. The first adapter line L1 is configured to connect the second bus portion 12 located in the non-display region NAA and the first power signal line V1 located in the display region AA to transmit the current on the second bus portion 12 to the first power signal line V1. The second bus portion 12 in the arc angle region 01 is electrically connected to the first power signal line V1 through the first adapter line L1. As shown in FIG. 6, the second bus portion 12 in the side region may also be electrically connected to the first power signal line V1 through the first adapter line L1, as shown in FIG. 8. The first adapter line L1 is located on the third metal layer. There is no need to dispose an additional film for preparing the first adapter L1 to reduce the thickness of the display panel. In some embodiments, in an arrangement where the first power bus and the first electrode are disposed in the same layer, the first end of the first adapter wire L1 is electrically connected to the second bus portion 12 in a punching manner, and the second end of the first adapter line L1 is electrically connected to the first power signal line V1 located in the first metal layer in a punching manner.

Further referring to FIG. 3, for example, the third metal layer is a metal layer most adjacent to the layer where the first electrode is located among multiple metal layers.

Since the first adapter line L1 is located on the third metal layer, the first power bus and the first electrode are disposed in the same layer, and the first adapter line L1 needs to be connected to the second bus portion 12 in the first power bus, the third metal layer is a metal layer most adjacent to the layer where the first electrode is located among multiple metal layers, that is, the distance between the film where the first adapter line L1 is located and the film where the second bus portion 12 is located is relatively short. In this manner, the first adapter line L1 is connected to the second bus portion 12. For example, the two are connected in a punching manner, and the punching difficulty may be reduced, and the punching precision may be improved.

Further referring to FIG. 3, for example, the first metal layer is adjacent to the third metal layer.

The first metal layer and the third metal layer are two adjacent metal layers and are insulated by an insulating layer to avoid signal crosstalk. The first metal layer is adjacent to the third metal layer, and the distance between the film where the first adapter line L1 is located and the film where the second bus portion 12 is located is relatively short. In this manner, the first adapter line L1 is connected to the second bus portion 12. For example, the two are connected in a punching manner, and the punching difficulty may be reduced, and the punching precision may be improved.

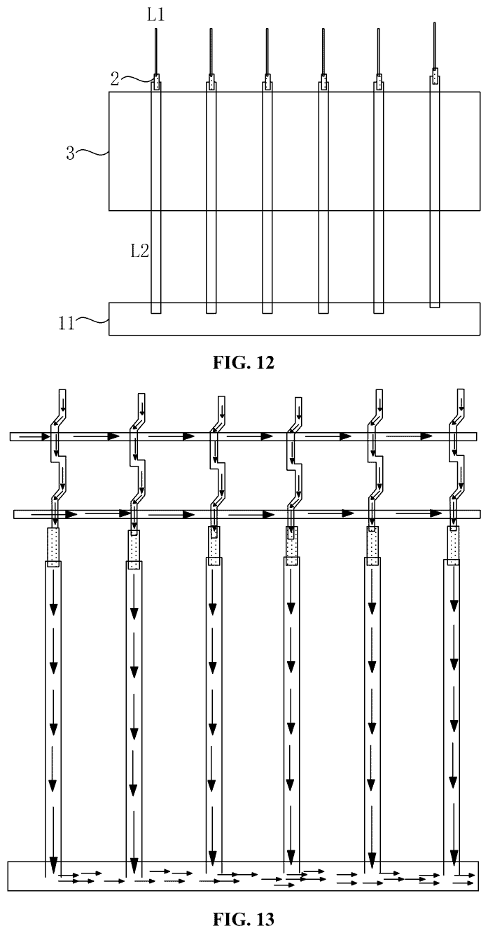

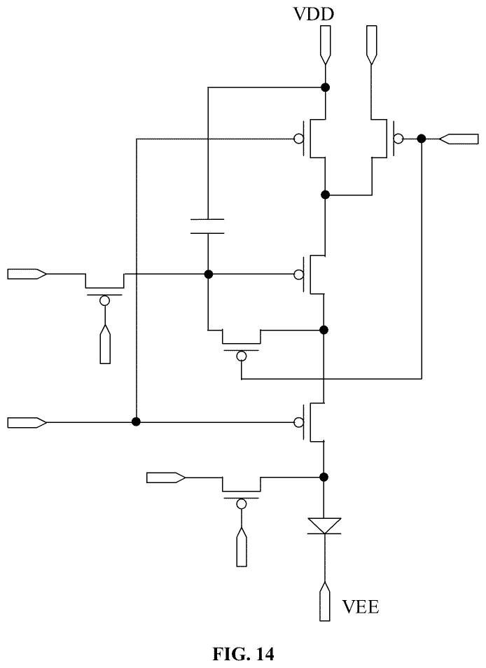

FIG. 12 is a layout diagram of a lower bezel region in the non-display region of a display panel shown in FIG. 3. FIG. 13 is a current simulation diagram of a lower bezel region in the non-display region of a display panel shown in FIG. 3. Referring to FIGS. 3, 12, and 13, for example, the display panel also includes a second adapter line L2. The second adapter line L2 is disposed on the same layer as the first power bus. A first end of the second adapter line L2 is connected to a second power signal line V2. A second end of the second adapter line L2 is connected to the first bus portion 11.

The second adapter line L2 is configured to connect a second power signal line V2 to the first bus portion 11. The second adapter line L2 is disposed on the same layer as the first power bus, to avoid punching additional holes or disposing conductive structures to connect the second adapter line L2 and the first bus portion 11. The second adapter line L2 may be located in the film where the first electrode (that is, the anode) is located, to guide the current in the display region to the first bus portion 11 and finally return the current to the power chip. One or more embodiments exemplarily show that the second adapter line L2 and the second power signal line V2 are located in different metal layers, and the two are connected through a via 2.

FIG. 14 is a diagram illustrating the structure of a pixel circuit in a display panel according to one or more embodiments of the present application. Referring to FIGS. 3, 12, 13, and 14, for example, the non-display region NAA also includes a second power bus 3 between the first bus portion 11 and the display region AA. The second power bus 3 is located in at least one metal layer of the multiple metal layers. The second adapter line L2 is insulated from the second power bus 3.

The second power bus 3 transmits a first power signal VDD to the anode of the light-emitting device. The first power bus transmits a second power signal VEE to the cathode of the light-emitting device. The second power bus 3 may be disposed on the same layer as the second adapter line L2. The second adapter line L2 is connected to the first bus portion 11 across the second power bus 3.

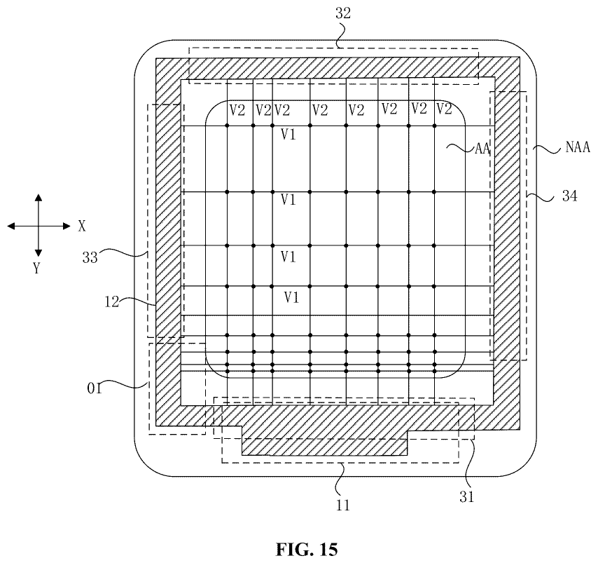

FIG. 15 is a diagram illustrating the structure of another display panel according to one or more embodiments of the present application. Referring to FIG. 15, for example, the non-display region NAA includes a first side region 31, a second side region 32, a third side region 33, and a fourth side region 34. The first side region 31 and the second side region 32 are disposed opposite to each other along the second direction Y. The third side region 33 and the fourth side region 34 are disposed opposite to each other along the first direction X. The first bus portion 11 is disposed in the first side region 31.

The first side region 31 may be the lower bezel region in the non-display region NAA. The second side region 32 may be the upper bezel region in the non-display region NAA. The third side region 33 may be the left bezel region in the non-display region NAA. The fourth side region 34 may be the right bezel region in the non-display region NAA. The power chip that provides a first power signal and a second power signal is generally disposed in the lower bezel region of the non-display region NAA. Thus, the first bus portion 11 is also disposed in the first side region 31 to be connected to the power chip.

Further referring to FIG. 15, for example, the non-display region NAA includes a first arc angle region and a second arc angle region. The first arc angle region includes a first lower arc angle region and a second lower arc angle region. The first lower arc angle region is adjacent to the first side region 31 and the third side region 33. The second lower arc angle region is adjacent to the first side region 31 and the fourth side region 34.

The second arc angle region includes a first upper arc angle region and a second upper arc angle region. The first upper arc angle region is adjacent to the second side region 32 and the third side region 33. The second upper arc angle region is adjacent to the second side region 32 and the fourth side region 34.

As described above, the distance between the first arc angle region and the first bus portion 11 is greater than the distance between the second arc angle region and the first bus portion 11.

Further referring to FIG. 15, for example, a first power signal line V1 connected to the second bus portion 12 in the first lower arc angle region and a first power signal line V1 connected to the second bus portion 12 in the second lower arc angle region are the same.

The second bus portion 12 in first lower arc angle region and the second bus portion 12 in the second lower arc angle region may be connected to multiple first power signal lines V1. One end of each first power signal line corresponding to the first lower arc angle region or the second lower arc angle region is connected to the second bus portion 12 in the first lower arc angle region through the first adapter line L1, and the other end of each first power signal line is connected to the second bus portion 12 in the second lower arc angle region through another first adapter line L1. A first power signal line V1 connected to the second bus portion 12 in the first lower arc angle region and a first power signal line V1 connected to the second bus portion 12 in the second lower arc angle region are the same. In this manner, the shunting effect for the second bus portion 12 in the first lower arc angle region and the shunting effect for the second bus portion 12 in the second lower arc angle region may be ensured, and, the number of first power signal lines V1 is reduced, and the wiring design in the display region AA is simplified. In one embodiment, a first power signal line V1 connected to the second bus portion 12 in the first lower arc angle region and a first power signal line V1 connected to the second bus portion 12 in the second lower arc angle region are the same, and the display brightness of the light-emitting devices at the same distance from the first bus portion 11 in the second direction Y is more uniform in the same grayscale.

Further referring to FIG. 3, for example, a first power signal line V1 connected to the second bus portion 12 in the first upper arc angle region and a first power signal line V1 connected to the second bus portion 12 in the second upper arc angle region are the same.

The second bus portion 12 in the first upper arc angle region and the second bus portion 12 in the second upper arc angle region may be connected to multiple first power signal lines V1. One end of each first power signal line V1 corresponding to the first upper arc angle region or the second upper arc angle region is connected to the second bus portion 12 in the first upper arc angle region through the first adapter line L1, and the other end of each first power signal line V1 is connected to the second bus portion 12 in the second upper arc angle region through another first adapter line L1. A first power signal line V1 connected to the second bus portion 12 in the first upper arc angle region and a first power signal line V1 connected to the second bus portion 12 in the second upper arc angle region are the same. In this manner, the shunting effect for the second bus portion 12 in the first upper arc angle region and the shunting effect for the second bus portion 12 in the second upper arc angle region may be ensured, and moreover, the number of first power signal lines V1 is reduced, and the wiring design in the display region AA is simplified.

Further referring to FIG. 3, for example, the second bus portion 12 in the third side region 33 and the second bus portion 12 in the fourth side region 34 are electrically connected to one or more first power signal lines V1.

There may also be current aggregation in the second bus portion 12 in the third side region 33 and the second bus portion 12 in the fourth side region 34. The currents on the second bus portion 12 in the third side region 33 and the second bus portion 12 in the fourth side region 34 are shunted to the display region, and the current densities in the third side region 33 and the fourth side region 34 may be reduced, to further reduce the heating of the display panel caused by a high current density. In one embodiment, the current is shunted by multiple first signal lines V1, and the IR Drop of a cathode signal is reduced, and the power consumption of the screen is reduced.

Further referring to FIG. 3, for example, the second bus portion 12 in the second side region 32 is electrically connected to the second power signal lines V2.

After the second bus portion 12 in the second side region 32 is electrically connected to the second power signal lines V2, the current on the second bus portion 12 in the second side region may be shunted to the display region to reduce the current density on the second bus portion 12 in the second side region and prevent the second side region from heating due to the excessive current density, to further reduce the temperature of the entire display panel. In one embodiment, the first power signal lines V1 further reduce the IR Drop of the cathode signal, and the power consumption of the screen is reduced.

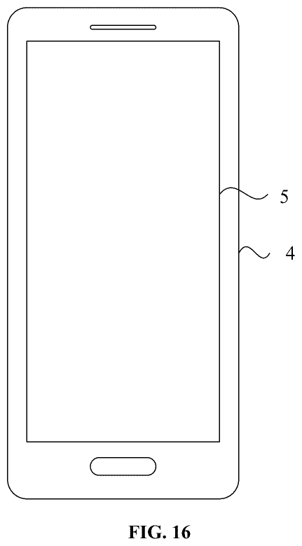

One or more embodiments of the present application provide a display device. FIG. 16 is a diagram illustrating the structure of a display device according to one or more embodiments of the present application. The display device 4 includes the preceding display panel 5. The display device 4 includes the preceding display panel 5. The display device 4 may be a mobile phone as shown in FIG. 16 or may be a computer, a television, or an intelligent wearable display device. This is not limited in the embodiments of the present application.

It is to be understood that various forms of processes shown in the preceding may be adopted with steps reordered, added, or deleted. For example, multiple steps described in the present application may be performed in parallel, sequentially, or in different sequences, as long as the desired results of the embodiments of the present application can be achieved, and no limitation is imposed herein.

What is claimed is:

1. A display panel, comprising a display region and a non-display region surrounding the display region, wherein the non-display region comprises at least one arc angle region, and the display panel further comprises:
a first power bus disposed in the non-display region, surrounding at least part of the display region, and passing through the at least one arc angle region, wherein the first power bus comprises a first bus portion and a second bus portion, the first bus portion is disposed on a side of the display region and is electrically connected to the second bus portion, and the first bus portion is configured to be connected to a power supply; and
a plurality of power signal lines disposed in the display region, wherein at least one of the plurality of power signal lines is electrically connected between the second bus portion in the at least one arc angle region and the first bus portion.

2. The display panel according to claim 1, wherein the at least one arc angle region of the non-display region comprises a first arc angle region and a second arc angle region, and a distance between the first arc angle region and the first bus portion is greater than a distance between the second arc angle region and the first bus portion;
the second bus portion in the second arc angle region is electrically connected to the first bus portion through at least one of the plurality of power signal lines; and
the first bus portion and the second bus portion are an integrated structure.

3. The display panel according to claim 1, wherein the non-display region further comprises one or more side regions adjacent to the at least one arc angle region, and the second bus portion in at least one side region of the one or more side regions is electrically connected to the first bus portion through at least one of the plurality of power signal lines.

4. The display panel according to claim 3, wherein the plurality of power signal lines comprise a plurality of first power signal lines and a plurality of second power signal lines, the plurality of first power signal lines extend in a first direction, the plurality of second power signal lines extend in a second direction, and the first direction and the second direction intersect;
the plurality of first power signal lines are electrically connected to the plurality of second power signal lines;
in the second direction, the first bus portion is located on the side of the display region;
the first bus portion is electrically connected to the plurality of second power signal lines; and
the second bus portion in the at least one arc angle region is electrically connected to at least one of the plurality of first power signal lines.

5. The display panel according to claim 4, wherein the second bus portion in the at least one side region is electrically connected to at least one of the plurality of first power signal lines.

6. The display panel according to claim 4, wherein the display region comprises a first display sub-region and a second display sub-region, the second display sub-region is located on a side of the first display sub-region facing away from the first bus portion, a density of first power signal lines in the second display sub-region is less than a density of first power signal lines in the first display sub-region.

7. The display panel according to claim 6, wherein in a direction from the second display sub-region to the first display sub-region, a density of first power signal lines gradually increases.

8. The display panel according to claim 4, further comprising a substrate and an array film on the substrate, wherein the array film comprises a plurality of metal layers; and
the plurality of first power signal lines and the plurality of second power signal lines are disposed in at least one of the plurality of metal layers.

9. The display panel according to claim 8, wherein the plurality of metal layers comprise a light-shielding layer, the light-shielding layer is located between an active layer in the array film and the substrate, and the plurality of first power signal lines and the plurality of second power signal lines are located in the light-shielding layer; and
an orthographic projection of the light-shielding layer on the substrate covers at least part of an orthographic projection of the active layer on the substrate.

10. The display panel according to claim 8, wherein the plurality of metal layers comprise a first metal layer and a second metal layer, the plurality of first power signal lines are located in the first metal layer, the plurality of second power signal lines are located in the second metal layer, and the second metal layer is located on a side of the first metal layer facing the substrate.

11. The display panel according to claim 10, further comprising a first electrode and a second electrode, wherein the second electrode is disposed on a side of the first electrode facing away from the array film, and the second bus portion is electrically connected to the second electrode.

12. The display panel according to claim 11, wherein the first power bus and the first electrode are disposed in a same layer, and the first power bus is insulated from the first electrode.

13. The display panel according to claim 11, wherein at least one of the following configurations is satisfied:
the display panel further comprises a first adapter line located in a third metal layer among the plurality of metal layers, wherein the third metal layer is located on a side of the first metal layer facing away from the substrate; a first end of the first adapter wire is electrically connected to the second bus portion, and a second end of the first adapter line is electrically connected to a first power signal line of the plurality of first power signal lines; the third metal layer is a metal layer most adjacent to a layer where the first electrode is located among the plurality of metal layers; and the first metal layer is adjacent to the third metal layer; and
the display panel further comprises a second adapter line disposed on a same layer as the first power bus, wherein a first end of the second adapter line is connected to a second power signal line of the plurality of second power signal lines, and a second end of the second adapter line is connected to the first bus portion; and the non-display region further comprises a second power bus between the first bus portion and the display region, the second power bus is located in at least one of the plurality of metal layers, and the second adapter line is insulated from the second power bus.

14. The display panel according to claim 4, wherein the non-display region comprises a first side region, a second side region, a third side region, and a fourth side region, the first side region and the second side region are disposed opposite to each other along the second direction, the third side region and the fourth side region are disposed opposite to each other along the first direction, and the first bus portion is disposed in the first side region.

15. The display panel according to claim 14, wherein the non-display region further comprises a first arc angle region and a second arc angle region;
the first arc angle region comprises a first lower arc angle region and a second lower arc angle region, the first lower arc angle region is adjacent to the first side region and the third side region, and the second lower arc angle region is adjacent to the first side region and the fourth side region; and
the second arc angle region comprises a first upper arc angle region and a second upper arc angle region, the first upper arc angle region is adjacent to the second side region and the third side region, and the second upper arc angle region is adjacent to the second side region and the fourth side region.

16. The display panel according to claim 15, wherein the second bus portion in the first lower arc angle region and the second bus portion in the second lower arc angle region are connected to a same first power signal line.

17. The display panel according to claim 15, wherein the second bus portion in the first upper arc angle region and the second bus portion in the second upper arc angle region are connected to a same first power signal line.

18. The display panel according to claim 14, wherein the second bus portion in the third side region and the second bus portion in the fourth side region are electrically connected to at least one of the plurality of first power signal lines.

19. The display panel according to claim 14, wherein the second bus portion in the second side region is electrically connected to the plurality of second power signal lines.

20. A display device, comprising a display panel, wherein the display panel comprises a display region and a non-display region surrounding the display region, the non-display region comprises at least one arc angle region, and the display panel further comprises:
a first power bus disposed in the non-display region, surrounding at least part of the display region, and passing through the at least one arc angle region, wherein the first power bus comprises a first bus portion and a second bus portion, the first bus portion is disposed on a side of the display region and is electrically connected to the second bus portion, and the first bus portion is configured to be connected to a power supply; and
a plurality of power signal lines disposed in the display region, wherein at least one of the plurality of power signal lines is electrically connected between the second bus portion in the at least one arc angle region and the first bus portion.
